(19) United States
(12) Patent Application Publication
(10) Pub. No.: US 2026/0026005 A1
(43) Pub. Date: Jan. 22, 2026

(54) DIELECTRIC GAS REGION FORMATION BETWEEN WORD LINE STRUCTURES USING A LAYER STACK INCLUDING INTERLEAVED SEMICONDUCTOR AND NITRIDE LAYERS

(71) Applicant: Micron Technology, Inc., Boise, ID (US)

(72) Inventors: Matthew KING, Boise, ID (US); Justin SHEPHERDSON, Meridian, ID (US); Patrick FLYNN, Boise, ID (US); Dmitry MIKULIK, Meridian, ID (US); Jeslin WU, Boise, ID (US); Yucheng WANG, Shanghai (CN); Gurpreet LUGANI, Boise, ID (US); Thanh Tung LE, Boise, ID (US); Nathan Philip DICE, Mt. Home, ID (US)

(21) Appl. No.: 19/216,869

(22) Filed: May 23, 2025

Related U.S. Application Data
(60) Provisional application No. 63/672,132, filed on Jul. 16, 2024.

(51) Int. Cl. H10B 43/35; H10B 41/27; H10B 41/35; H10B 41/41; H10B 43/27; H10B 43/40

(52) U.S. Cl. CPC H10B 43/35; H10B 41/27; H10B 41/35; H10B 41/41; H10B 43/27; H10B 43/40

(57) ABSTRACT

Embodiments described herein relate to various structures, integrated assemblies, and memory devices. In some embodiments, a memory device includes a memory block region having a pillar structure, a first word line structure that extends away from the pillar structure along a first level, a second word line structure that extends away from the pillar structure along a second level, and a dielectric gas region along a third level that is between facing surfaces of the first word line structure and the second word line structure. The memory device includes a periphery region proximate the memory block region. The periphery region includes a tiered structure that includes a first nitride layer formed along the first level, a second nitride layer formed along the second level, and a semiconductor layer formed along the third level.

### CROSS-REFERENCE TO RELATED APPLICATION

This patent application claims priority to U.S. Provisional Patent Application No. 63/672,132, filed on Jul. 16, 2024, entitled “DIELECTRIC GAS REGION FORMATION BETWEEN WORD LINE STRUCTURES USING A LAYERSTACK INCLUDING INTERLEAVED SEMICONDUCTOR AND NITRIDE LAYERS,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to formation of a dielectric gas region between word line structures using interleaved semiconductor and nitride layers.

### BACKGROUND

Memory devices provide data storage for electronic systems. Flash memory is a type of non-volatile memory, meaning that the memory retains data in the absence of a power supply. As an example, an electronic device may use flash memory in a solid-state drive (SSD) for non-volatile storage of information, rather than a hard disk drive that uses magnetic disks for storage. NAND is a type of flash memory that has advantages over hard disk drives, such as lower erase times, lower write times, and less chip area per memory cell, which allows for more storage density and lower cost. The memory cells in NAND memory may be configured or formed in vertical stacks. This arrangement is sometimes called vertical NAND or three-dimensional (3D) NAND. 3D NAND arrangements enable a greater quantity of memory cells per chip surface area because of the vertical stacking of memory cells. 3D NAND arrangements also enable more options for the placement of cells to avoid interference and electron leakage, which can improve memory device performance. As the demand for storage capacity and performance increases, improvements in NAND architecture and improved methods for fabricating NAND memory are desirable.

### BRIEF DESCRIPTION OF THE DRAWINGS

FIG. 1 is a diagram illustrating an example of components included in a memory device described herein.

FIG. 2 is a diagram illustrating an example of a NAND memory array described herein.

FIG. 3 is a diagram illustrating an example of a 3D NAND memory array described herein.

FIGS. 4A and 4B are diagrammatic views related to an example memory device structure described herein.

FIG. 5 is a diagrammatic view including example embodiments of a tiered structure described herein.

FIG. 6 is a flowchart of an example method of forming an integrated assembly or memory device having dielectric gas regions between word line structures using a layer stack including interleaved semiconductor and nitride layers.

FIG. 7 is a flowchart of an example method of forming an integrated assembly or memory device having dielectric gas regions between word line structures using a layer stack including interleaved semiconductor and nitride layers.

FIGS. 8A through 8G are diagrammatic views showing formation of a memory device structure at example process stages of an example process of forming the memory device structure.

FIGS. 9A through 9G are diagrammatic views showing formation of a memory device structure at example process stages of an example process of forming the memory device structure.

### DETAILED DESCRIPTION

A semiconductor device (e.g., a NAND memory device) may include a tiered structure of alternating dielectric layers and conductive layers. The conductive layers may be used to form integrated circuitry of a memory device, such as access lines (e.g., word lines) that are used to select and activate memory cells included in the memory device for data reading or data writing operations. The semiconductor device may include contacts that connect with the tiered structure and provide electrical coupling between a particular conductive layer (e.g., an access line) and a bit line, as well as pillar structures that penetrate through the tiered structure to integrate channels and memory cells of the semiconductor device. The dielectric layers may electrically isolate the conductive layers (e.g., access lines) to allow selection of particular memory cells integrated with the pillar structures.

The semiconductor device may have intentionally-formed dielectric gas regions (e.g., air gaps), between facing surfaces of the access lines, that serve as insulating regions between the access lines, preventing electrical interference or crosstalk. The insulating regions maintain integrity of stored data in the semiconductor device by reducing the potential for unintended electrical interactions between neighboring memory cells. Furthermore, the presence of the air gaps contributes to enhanced reliability and performance of the semiconductor device, ensuring that data can be accurately read from and written to the memory cells without interference from adjacent components.

To form a pillar structure, a cavity having a high aspect ratio (e.g., a high depth-to-width ratio) may be formed in a layer stack that is eventually replaced during formation of the word line structures or dielectric gas regions. To satisfy one or more design or performance thresholds associated with the high aspect ratio, and to be compatible with a dry etch operation used to form the cavity, the layer stack may include nitride layers interleaved with oxide layers. However, and as part of forming the access lines or the dielectric gas regions, subsequent operations that replace the nitride and oxide layers may damage outer layers of the pillar structure, cause oxidation to metal layers included in the access lines, or cause electrical shorting between the word lines.

Some embodiments described herein include a semiconductor device having a pillar structure, word line structures extending away from the pillar structure, and dielectric gas regions (e.g., air gaps) between facing surfaces of the word line structures. Techniques to form the semiconductor device include using a layer stack having nitride layers interleaved with semiconductor layers. In some embodiments, and as part of forming the pillar structure, the techniques include using a cryogenic etch operation to form a cavity having a high aspect ratio in the layer stack. After forming the pillar structure in the cavity, and as part of forming the word line structures and the dielectric gas regions, the techniques include using combinations of operations that replace the nitride layers or the semiconductor layers.

In this way, the combinations of operations that form the word line structures and the dielectric gas regions may be performed with negligible damage to outer layers of the pillar structure or negligible oxidation to the word line structures. As a result, a likelihood of electrical shorting defects between the word line structures may be reduced, to improve quality or reliability of the semiconductor device.

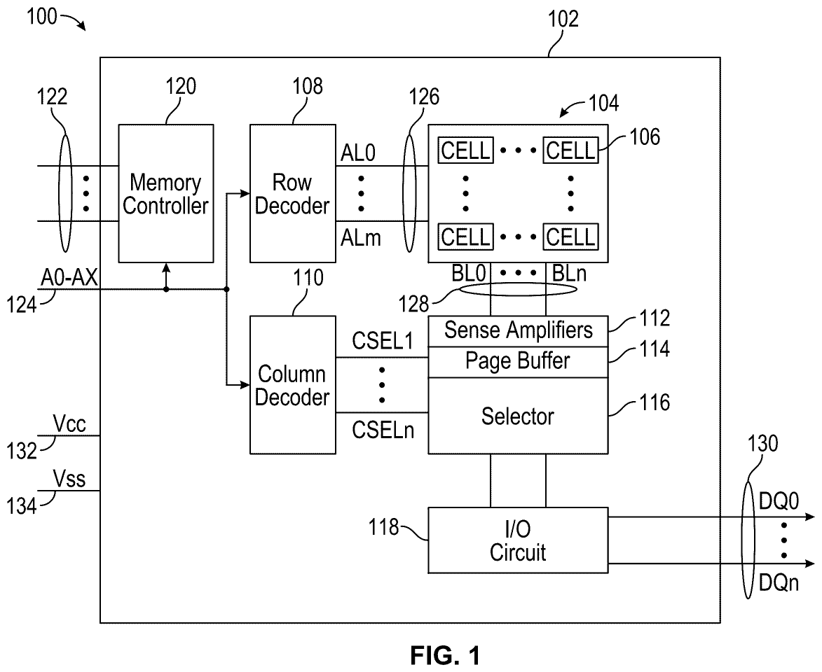

FIG. 1 is a diagram illustrating an example 100 of components included in a memory device 102 described herein. The memory device 102 may include a memory array 104 having multiple memory cells 106. The memory device 102 may include one or more components (e.g., circuits) to transmit signals to or perform memory operations on the memory array 104. For example, the memory device 102 may include a row decoder 108, a column decoder 110, one or more sense amplifiers 112, a page buffer 114, a selector 116, an input/output (I/O) circuit 118, and a memory controller 120.

The memory controller 120 may control memory operations of the memory device 102 according to one or more signals received via one or more control lines 122, such as one or more clock signals or control signals that indicate an operation (e.g., write, read, or erase) to be performed. The memory controller 120 may determine one or memory cells 106 upon which the operation is to be performed based on one or more signals received via one or more address lines 124, such as one or more address signals (shown as A0-AX). A host device external from the memory device 102 may control the values of the control signals on the control lines 122 or the address signals on the address line 124.

The memory device 102 may use access lines 126 (sometimes called word lines or row lines, and shown as AL0-ALm) and bit lines 128 (sometimes called digit lines, data lines, or column lines, and shown as BL0-BLn) to transfer data to or from one or more of the memory cells 106. For example, the row decoder 108 and the column decoder 110 may receive and decode the address signals (A0-AX) from the address line 124 and may determine which of the memory cells 106 are to be accessed based on the address signals. The row decoder 108 and the column decoder 110 may provide signals to those memory cells 106 via one or more access lines 126 and one or more bit lines 128, respectively.

For example, the column decoder 110 may receive and decode address signals into one or more column select signals (shown as CSEL1-CSELn). The selector 116 may receive the column select signals and may select data in the page buffer 114 that represents values of data to be read from or to be programmed into memory cells 106. The page buffer 114 may be configured to store data received from a host device before the data is programmed into relevant portions of the memory array 104, or the page buffer 114 may store data read from the memory array 104 before the data is transmitted to the host device. The sense amplifiers 112 may be configured to determine the values to be read from or written to the memory cells 106 using the bit lines 128. For example, in a selected string of memory cells 106, a sense amplifier 112 may read a logic level in a memory cell 106 in response to a read current flowing through the selected string to a bit line 128. The I/O circuit 118 may transfer values of data into or out of the memory device 102 (e.g., to or from a host device), such as into or out of the page buffer 114 or the memory array 104, using I/O lines 130 (shown as (DQ0-DQn)).

The memory controller 120 may generate or receive positive and negative supply signals, such as a supply voltage (Vcc) 132 and a negative supply (Vss) 134 (e.g., a ground potential), from an external source or power supply (e.g., an internal battery, an external battery, or an AC-to-DC converter).

As indicated above, FIG. 1 is provided as an example. Other examples may differ from what is described with regard to FIG. 1.

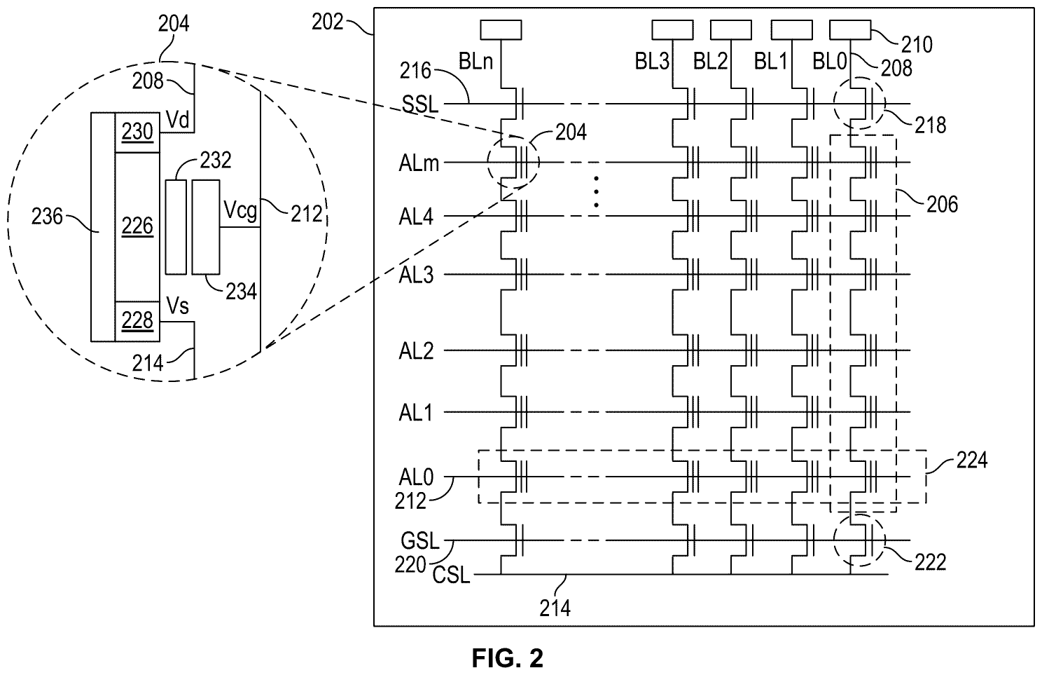

FIG. 2 is a diagram illustrating an example 200 of a NAND memory array 202 described herein. The NAND memory array 202 may correspond to the memory array 104 described above in connection with FIG. 1. The memory array 202 may be part of a three-dimensional stack of memory arrays, such as 3D NAND flash memory.

The memory array 202 includes multiple memory cells 204. A memory cell 204 may store an analog value, such as an electrical voltage or an electrical charge, that represents a data state (e.g., a digital value). The analog value and corresponding data state depend on a quantity of electrons trapped or present within a region of the memory cell 204 (e.g., in a charge trap, such as a floating gate), as described below.

A NAND string 206 (sometimes called a string) may include multiple memory cells 204 connected in series. A NAND string 206 is coupled to a bit line 208 (sometimes called a digit line or a column line, and shown as BL0-BLn). Data can be read from or written to the memory cells 204 of a NAND string 206 via a corresponding bit line 208 using one or more input/output (I/O) components 210 (e.g., an I/O circuit, an I/O bus, a page buffer, or a sensing component, such as a sense amplifier). Memory cells 204 of different NAND strings 206 (e.g., one memory cell 204 per NAND string 206) may be coupled with one another via access lines 212 (sometimes called word lines or row lines, and shown as AL0-ALm) that select which row (or rows) of memory cells 204 is affected by a memory operation (e.g., a read operation or a write operation).

A NAND string 206 may be connected to a bit line 208 at one end and a common source line (CSL) 214 at the other end. A string select line (SSL) 216 may be used to control respective string select transistors 218. A string select transistor 218 selectively couples a NAND string 206 to a corresponding bit line 208. A ground select line (GSL) 220 may be used to control respective ground select transistors 222. A ground select transistor 222 selectively couples a NAND string 206 to the common source line 214.

A “page” of memory (or “a memory page”) may refer to a group of memory cells 204 connected to the same access line 212, as shown by reference number 224. In some implementations (e.g., for single-level cells), the memory cells 204 connected to an access line 212 may be associated with a single page of memory. In some implementations (e.g., for multi-level cells), the memory cells 204 connected to an access line 212 may be associated with multiple pages of memory, where each page represents one bit stored in each of the memory cells 204 (e.g., a lower page that represents a first bit stored in each memory cell 204 and an upper page that represents a second bit stored in each memory cell 204). In NAND memory, a page is the smallest physically addressable data unit for a write operation (sometimes called a program operation).

In some implementations, a memory cell 204 is a floating-gate transistor memory cell. In this case, the memory cell 204 may include a channel 226, a source region 228, a drain region 230, a floating gate 232, and a control gate 234. The source region 228, the drain region 230, and the channel 226 may be on a substrate 236 (e.g., a semiconductor substrate). A memory device may store a data state in the memory cell 204 by charging the floating gate 232 to a particular voltage associated with the data state or to a voltage that is within a range of voltages associated with the data state. This results in a predefined amount of current flowing through the channel 226 (e.g., from the source region 228 to the drain region 230) when a specified read voltage is applied to the control gate 234 (e.g., by a corresponding access line 212 connected to the control gate 234). Although not shown, a tunnel oxide layer (or tunnel dielectric layer) may be interposed between the floating gate 232 and the channel 226, and a gate oxide layer (e.g., a gate dielectric layer) may be interposed between the floating gate 232 and the control gate 234. As shown, a drain voltage Vd may be supplied from a bit line 208, a control gate voltage Veg may be supplied from an access line 212, and a source voltage Vs may be supplied via the common source line 214 (which, in some implementations, is a ground voltage).

To write or program the memory cell 204, Fowler-Nordheim tunneling may be used. For example, a strong positive voltage potential may be created between the control gate 234 and the channel 226 (e.g., by applying a large positive voltage to the control gate 234 via a corresponding access line 212) while current is flowing through the channel 226 (e.g., from the common source line 214 to the bit line 208, or vice versa). The strong positive voltage at the control gate 234 causes electrons within the channel 226 to tunnel through the tunnel oxide layer and be trapped in the floating gate 232. These negatively charged electrons then act as an electron barrier between the control gate 234 and the channel 226 that increases the threshold voltage of the memory cell 204. The threshold voltage is a voltage required at the control gate 234 to cause current (e.g., a threshold amount of current) to flow through the channel 226. Fowler-Nordheim tunneling is an example technique for storing a charge in the floating gate, and other techniques, such as channel hot electron injection, may be used.

To read the memory cell 204, a read voltage may be applied to the control gate 234 (e.g., via a corresponding access line 212), and an I/O component 210 (e.g., a sense amplifier) may determine the data state of the memory cell 204 based on whether current passes through the memory cell 204 (e.g., the channel 226) due to the applied voltage. A pass voltage may be applied to all memory cells 204 (other than the memory cell 204 being read) in the same NAND string 206 as the memory cell 204 being read. For example, the pass voltage may be applied on each access line 212 other than the access line 212 of the memory cell 204 being read (e.g., where the read voltage is applied). The pass voltage is higher than the highest read voltage associated with any memory cell data states so that all of the other memory cells 204 in the NAND string 206 conduct, and the I/O component 210 can detect a data state of the memory cell 204 being read by sensing current (or lack thereof) on a corresponding bit line 208. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 234 to distinguish between the three or more data states and determine a data state of the memory cell 204.

To erase the memory cell 204, a strong negative voltage potential may be created between the control gate 234 and the channel 226 (e.g., by applying a large negative voltage to the control gate 234 via a corresponding access line 212). The strong negative voltage at the control gate 234 causes trapped electrons in the floating gate 232 to tunnel back across the oxide layer from the floating gate 232 to the channel 226 and to flow between the common source line 214 and the bit line 208. This removes the electron barrier between the control gate 234 and the channel 226 and decreases the threshold voltage of the memory cell 204 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block or a subset of memory cells of the block.

As indicated above, FIG. 2 is provided as an example. Other examples may differ from what is described with regard to FIG. 2.

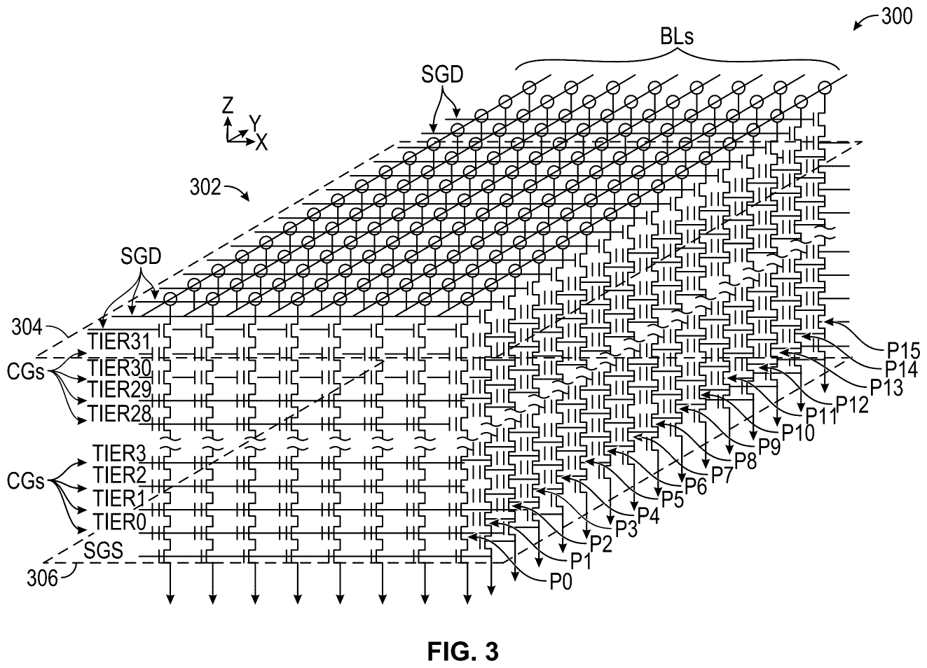

FIG. 3 is a diagram illustrating an example 300 of a 3D NAND memory array 302 described herein. The 3D NAND memory array 302 may correspond to the memory array 104 described above in connection with FIG. 1 or the NAND memory array 202 described above in connection with FIG. 2.

The 3D NAND memory array 302 includes multiple strings of memory cells. A string includes multiple tiers of charge storage transistors stacked in a first direction, shown as the Z direction. The charge storage transistors are stacked source to drain from a source-side select gate (SGS) to a drain-side select gate (SGD). In the example 300 of FIG. 3, each string includes 32 tiers (shown as TIER0 through TIER31). In other examples, each string of memory cells may include a different quantity of tiers (e.g., 8 tiers, 16 tiers, 64 tiers, or 128 tiers). The memory cells of a particular string may share a common channel region, such as one formed in a respective pillar of semiconductor material (e.g., polysilicon) about which the string of memory cells is formed.

Along a second direction, shown as the Y direction, multiple strings of memory cells are connected along bit lines (BLs). For example, a first group of strings is coupled to a first bit line extending in the second direction, a second group of strings is coupled to a second bit line extending in the second direction, and so on.

Along a third direction, shown as the X direction, memory cells in the same tier but in different strings are arranged in memory pages (shown as P0 through P15). For example, a group of memory cells in a tier may be coupled to the same access line to form a page (or multiple pages, in the example of multi-level cells). Within a page, each tier represents a row of memory cells, and each string of memory cells represents a column. A block of memory cells can include multiple pages, such as 128 pages or 384 pages.

Each memory cell includes a control gate (CG) coupled to an access line, as described above in connection with FIG. 2. The access line collectively couples the control gates of memory cells in a specific tier or a portion of a tier. A tier in the 3D NAND memory array 302, can be accessed or controlled using an access line. For example, the 3D NAND memory array 302 may include a first level of semiconductor material 304 (e.g., polysilicon) that couples the control gates of each memory cell in TIER31. Similar respective levels of metal or semiconductor material may couple the control gates for each respective tier. As further shown, the 3D NAND memory array 302 may include a second level of semiconductor material 306 that couples the source-side select gates (SGS) of the array. Specific strings of memory cells in the 3D NAND memory array 302 can be accessed, selected, or controlled using a combination of bit lines and select gates, and specific memory cells at one or more tiers in the specific strings can be accessed, selected, or controlled using one or more access lines.

As indicated above, FIG. 3 is provided as an example. Other examples may differ from what is described with regard to FIG. 3. For example, the number of memory cells, strings, tiers, bit lines, access lines, or pages may be greater than or less than those shown in FIG. 3.

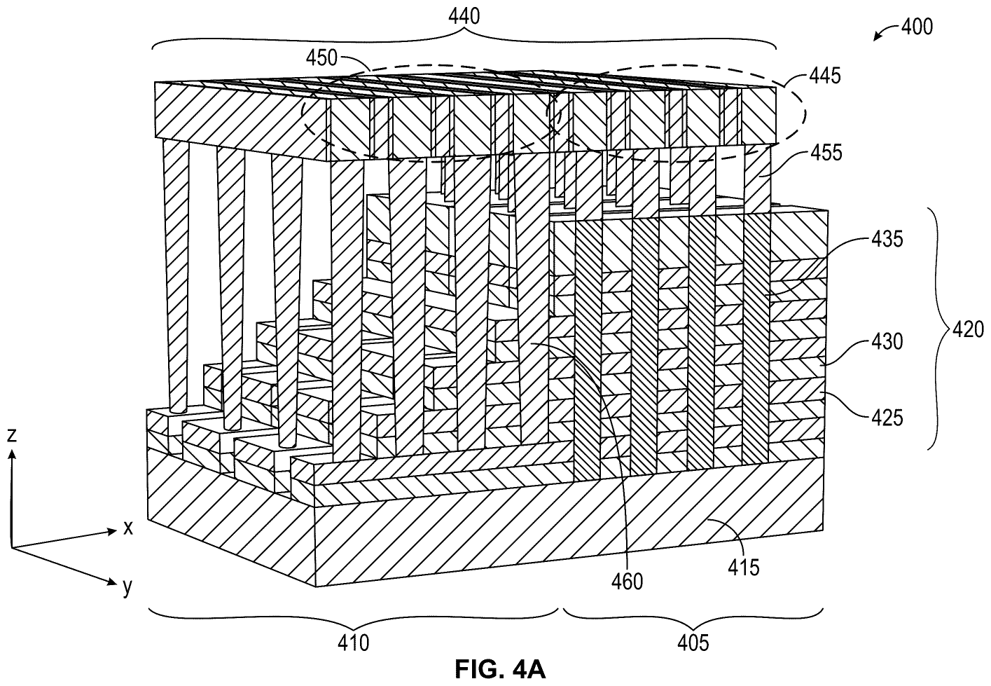

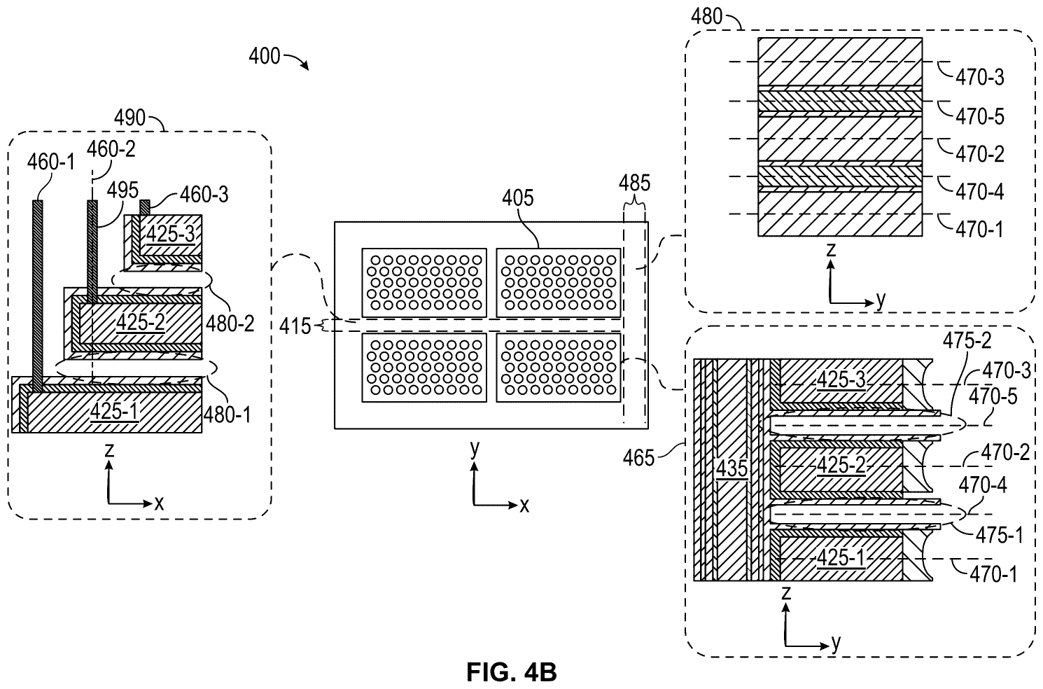

FIGS. 4A and 4B are diagrammatic views related to an example memory device structure 400 described herein. In some implementations, the memory device structure 400 corresponds to a structure of a three-dimensional (3D) NAND memory device as described in connection with FIG. 3.

As shown in the isometric section view of FIG. 4A, the memory device structure 400 includes a memory block region 405 and a staircase region 410. The memory block region 405 and the staircase region 410 each include portions of a substrate 415 and a tiered structure 420.

The substrate 415 may comprise, consist of, or consist essentially of semiconductive material. The semiconductive material may comprise, consist of, or consist essentially of silicon (e.g., polycrystalline silicon). Alternatively, and in some implementations, the substrate 415 comprises, consists of, or consists essentially of silicon carbide, gallium nitride, or a type III-V element.

The tiered structure 420 may include access lines 425 (sometimes called word lines herein) alternating with dielectric layers 430. In other words, the tiered structure 420 may include an arrangement of the access lines 425 and the dielectric layers 430 in a stack or layered structure, where the access lines 425 and the dielectric layers 430 alternate with one another within the stack. Each of the access lines 425 may be an electrical conductor and may comprise, consist of, or consist essentially of conductive material. As used herein, a conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide). In some implementations, the access lines 425 may be formed from conductive layers in the memory device structure 400.

Each of the dielectric layers 430 may be an electrical insulator and may comprise, consist of, or consist essentially of insulative material. As used herein, an insulative material may comprise, consist of, or consist essentially of an oxide (e.g., silicon oxide, aluminum oxide, or another suitable oxide material) or a nitride (e.g., silicon nitride aluminum nitride, or another suitable nitride material). A dielectric layer 430 may electrically isolate an access line 425 (e.g., a first access line) that is above the dielectric layer 430 in the stack and another access line 425 (e.g., a second access line) that is below the dielectric layer 430 in the stack.

Within the memory block region 405, one or more pillar structures 435 may penetrate through the tiered structure 420. The pillar structures 435 may each include an annular distribution (e.g., layered rings) of conductive materials or insulative materials that form a channel or a storage cell of the memory device structure 400. The pillar structures 435 may be elongated structures that are vertically-oriented (e.g., orthogonal to the substrate 415) and include approximately round cross-sections or approximately rectangular cross sections, among other examples.

The memory device structure 400 may further include an array of conductive structures 440. The array of conductive structures 440 may include one or more conductive materials and be laterally formed in at least one plane above the tiered structure 420.

The array of conductive structures 440 may include one or more bit lines 445 above the memory block region 405. The array of conductive structures 440 may further include connector lines 450 that correspond to control gate or source/select lines, among other examples. As shown in FIG. 4A, the bit lines 445 and the connector lines 450 are arranged in a parallel fashion in a common plane. However, and in other implementations, the bit lines 445 and the connector lines 450 may be arranged in an orthogonal fashion or distributed across multiple planes.

As shown in FIG. 4A, the memory device structure 400 may further include contact pillars 455 and contact pillars 460. The contact pillars 455 may be vertically-oriented (e.g., may be approximately orthogonal to the substrate 415), may support the bit lines 445, and may provide electrical coupling between the bit lines 445 and the pillar structures 435. The contact pillars 460 may be vertically-oriented, may support the connector lines 450, and may provide electrical coupling between the connector lines 450 and the access lines 425. The contact pillars 455 and the contact pillars 460 may each include one or more conductive materials as described above.

FIG. 4B shows additional details of the memory device structure 400. In some implementations, and as shown in magnified detail 465, the access lines 425 are formed along levels 470 that are approximately orthogonal to the pillar structure 435 (e.g., each of the levels 470 may be approximately parallel to one another). For example, the access line 425-1 is formed along the level 470-1, the access line 425-2 is formed along the level 470-2, and the access line 425-3 is formed along the level 470-3. In some embodiments, layers or materials of each of the access lines 425 may combine to form a word line structure.

As further shown in the magnified detail 465, one or more dielectric gas regions 475 (e.g., air gaps) may be between vertically adjacent access lines 425. In some embodiments, the dielectric gas regions 475 may include a vacuum as an alternative to air or another dielectric gas.

As examples, and as shown in FIG. 4B, the dielectric gas region 475-1 is along the level 470-4 that is between facing surfaces of the access line 425-1 and 425-2.

Additionally, or alternatively and as shown in FIG. 4B, the dielectric gas region 475-2 is along the level 470-5 that is between facing surfaces of the access lines 425-2 and 425-3.

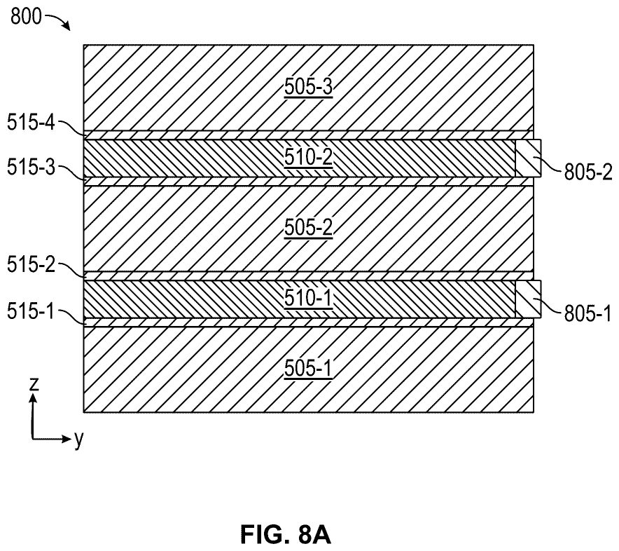

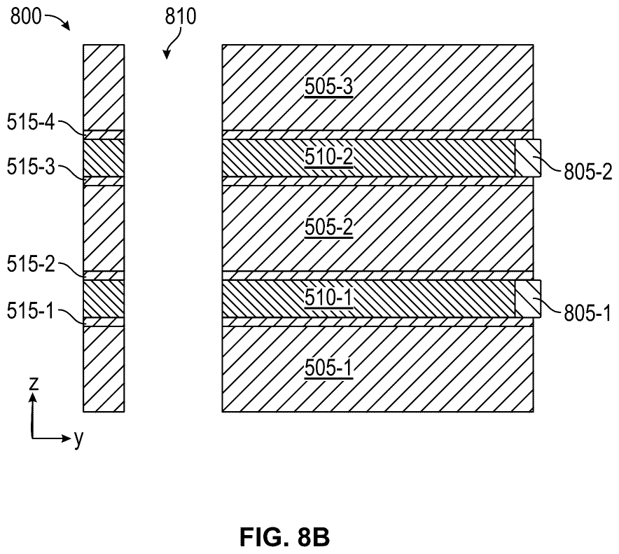

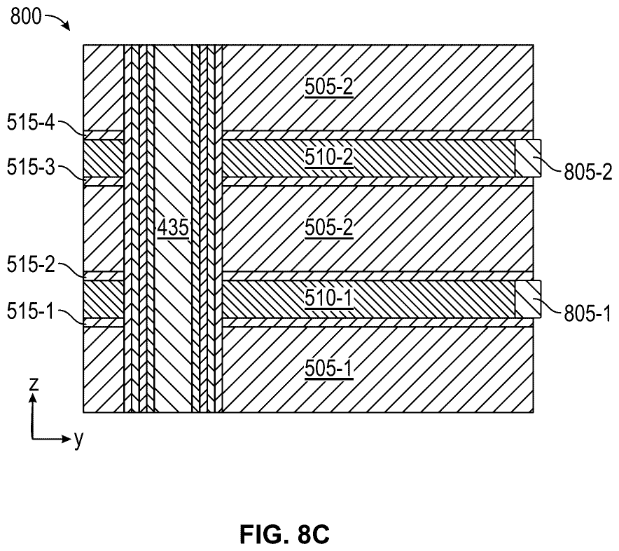

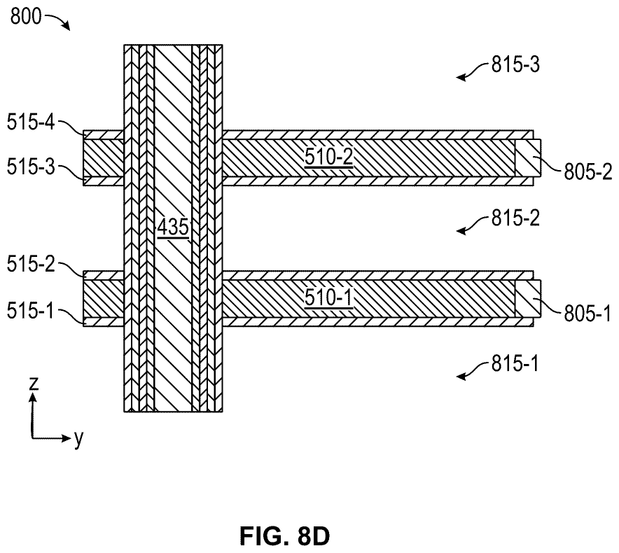

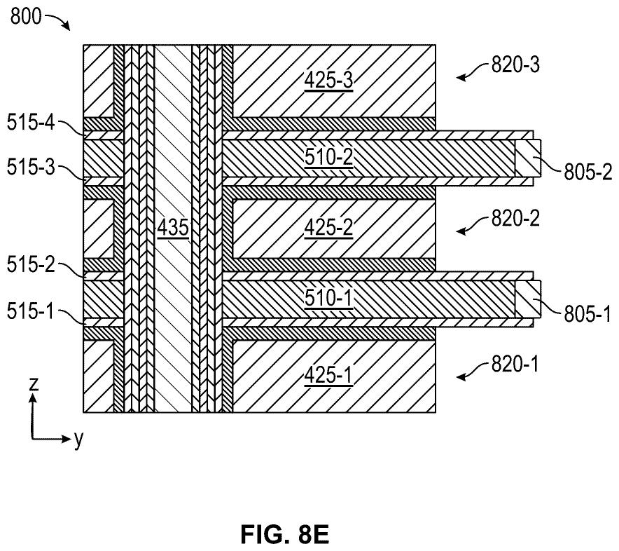

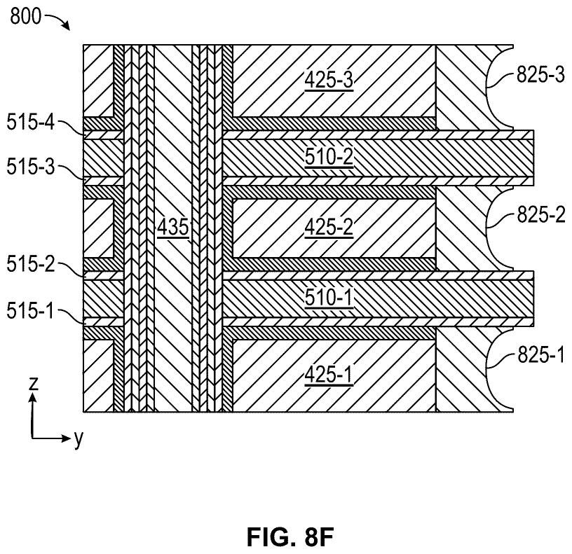

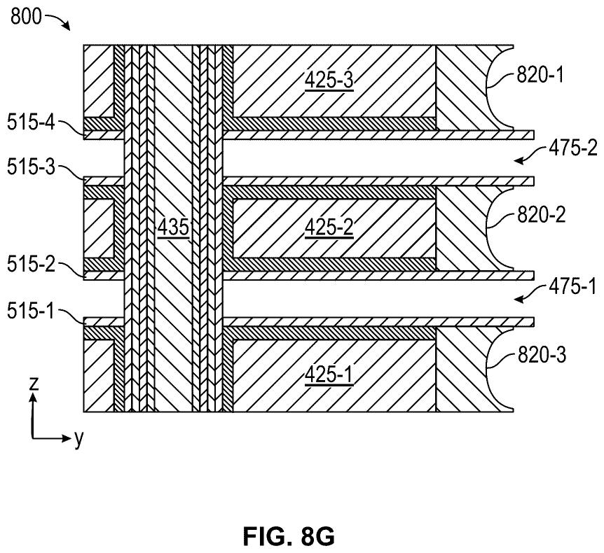

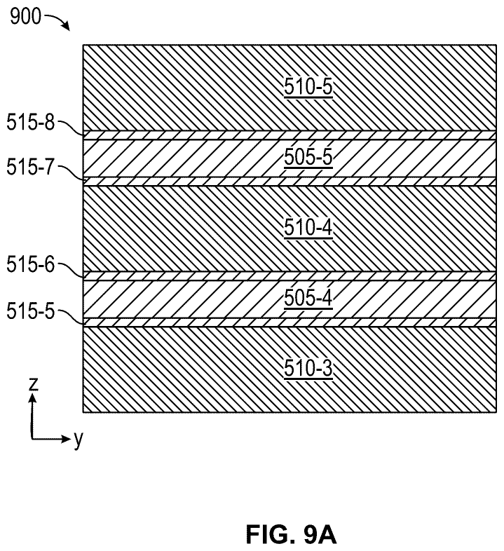

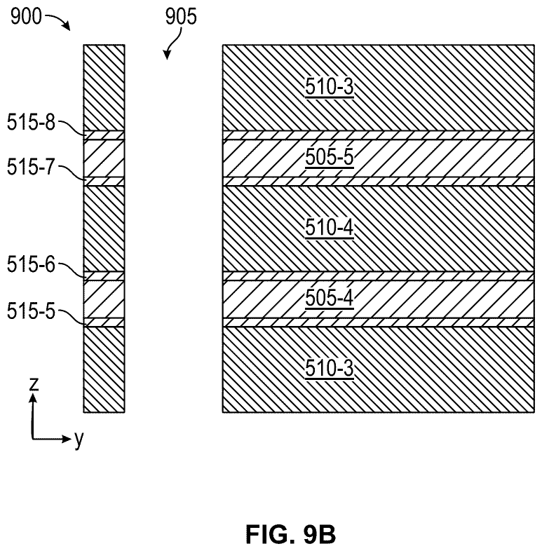

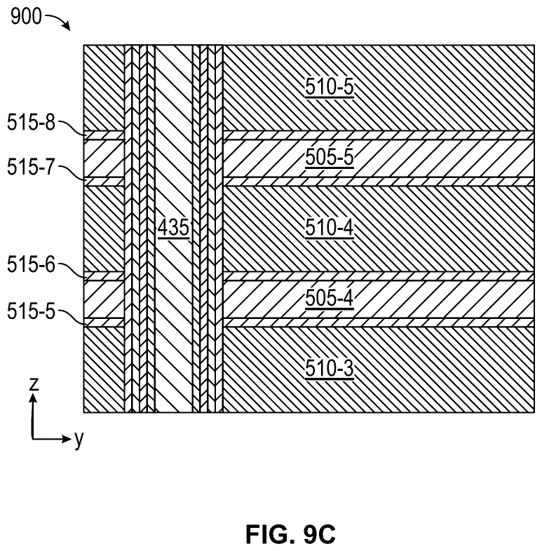

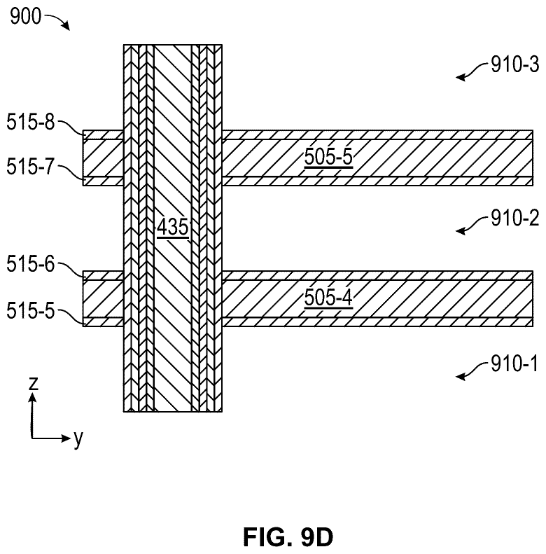

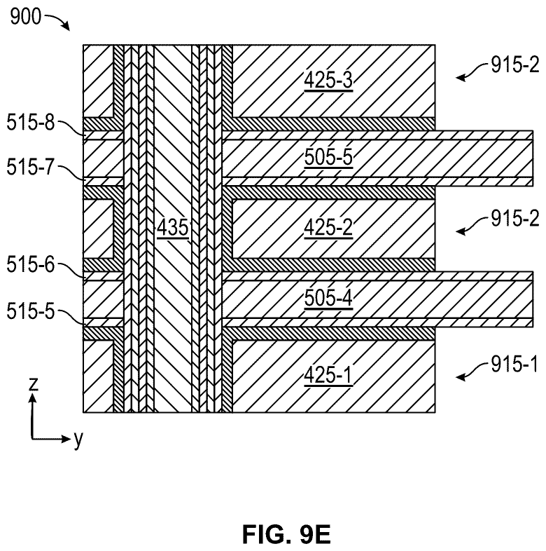

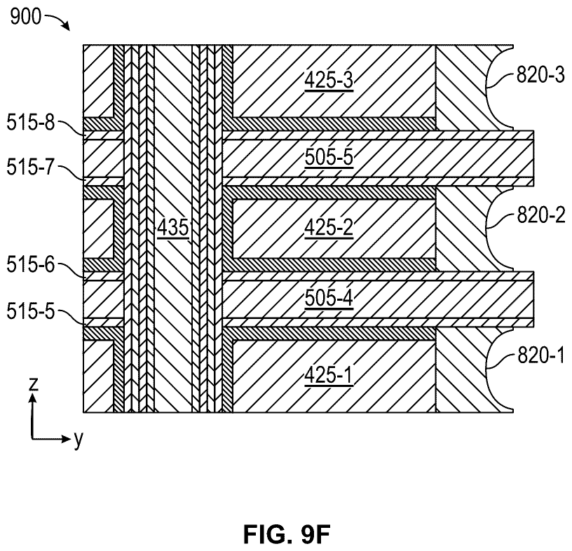

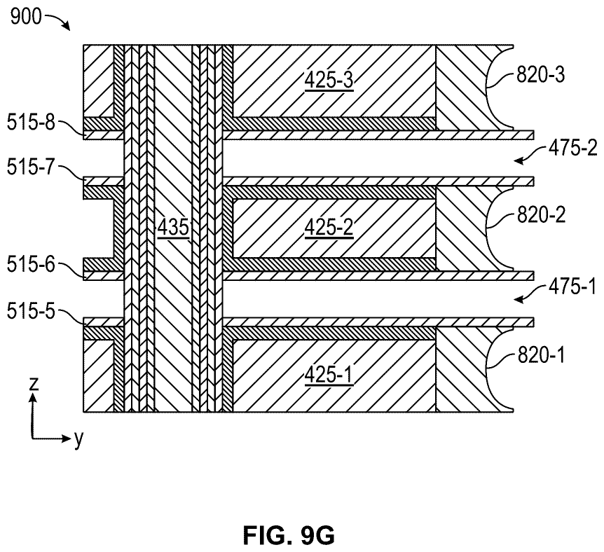

As shown in the magnified detail 480, a periphery region 485 may include a stack of layers including nitride layers that are interleaved with semiconductor layers, where each of the nitride layers or semiconductor layers is along one of the levels 470 (e.g., aligned with a corresponding word line structure or with a corresponding dielectric gas region). As described in greater detail in connection with FIGS. 8A-9G and elsewhere herein, the nitride layers or the semiconductor layers may temporarily extend into the memory block region 405 to enable replacement operations that form the access lines 425 or the dielectric gas region 475.

As shown in the magnified detail 490, the staircase region 410 includes a staggering of end portions of the access lines 425 to accommodate one or more contact pillars 460 that electrically connect the access lines 425 with integrated circuitry of a semiconductor device including the memory device structure 400. In some embodiments, and as shown in magnified detail 490, the dielectric gas regions 475 extend into the staircase region 410. In some embodiments, and as shown, one or more of the dielectric gas regions 475 may extend to or beyond a central axis 495 of one or more of the contact pillars 460.

As indicated above, FIGS. 4A and 4B are provided as an example. Other examples may differ from what is described with regard to FIGS. 4A and 4B.

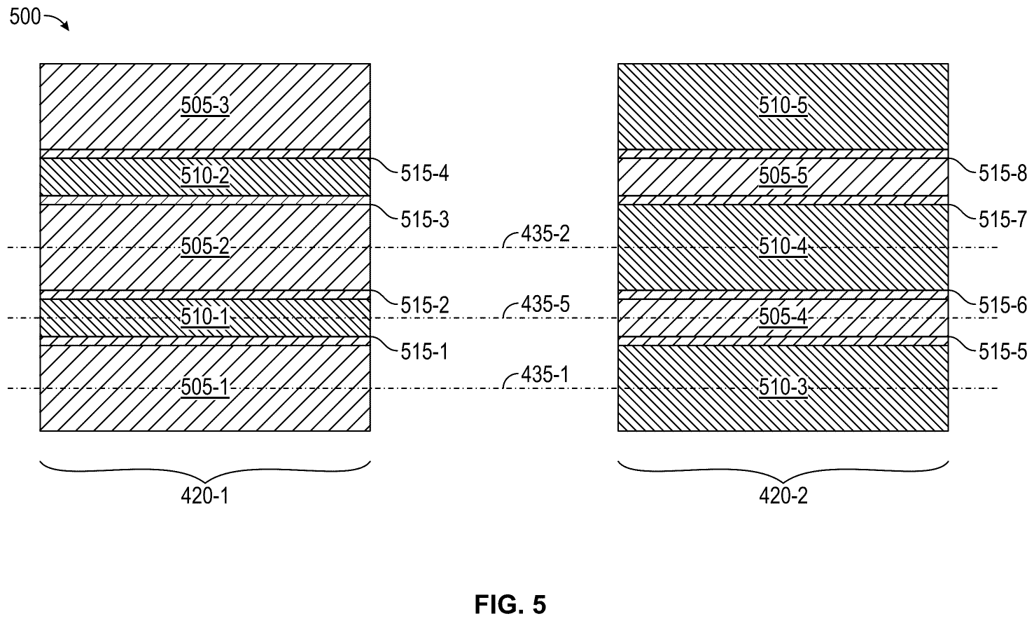

FIG. 5 is a diagrammatic view including example embodiments 500 of a tiered structure described herein. The embodiments 500 include the tiered structure 420-1 and the tiered 420-2, each including a vertically arranged stack of nitride layers 505 and semiconductor layers 510 that are interleaved with one another. In some embodiments, and as shown in FIG. 5, oxide layers 515 may be interleaved between the nitride layers 505 and the semiconductor layers 510.

In some embodiments, a material of the nitride layers 505 comprises, consists of, or consists essentially silicon nitride (Si₃N₄) or another suitable nitride material. Additionally, or alternatively and in some embodiments, a material of at least one of the semiconductor layers 510 comprises, consists of, or consists essentially of polysilicon (poly-Si), germanium (Ge), a silicon-germanium compound (SiGe), or another suitable semiconductor material. Additionally, or alternatively and in some embodiments, a material of at least one of the semiconductor layers 510 comprises, consists of, or consists essentially of a crystalline structure, a polycrystalline structure, or an amorphous structure. Additionally, or alternatively and in some embodiments, a material of at least one of the oxide layers 515 comprises, consists of, or consists essentially of silicon dioxide (SiO₂) or another suitable oxide material.

As shown in FIG. 5, a bottom-most layer of the tiered structure 420-1 includes the nitride layer 505-1. As a result, and in some embodiments, the tiered-structure 440-1 is referred to as an “NSNSN” configuration.

As part of the tiered structure 420-1, at least one of the nitride layers 505-1, 505-2, or 505-3 may have a thickness that is included in a range of approximately 17 nanometers (nm) to approximately 20 nm. However, other values and ranges for a thickness of the nitride layers 505-1, 505-2, or 505-3 are within the scope of the present disclosure, such as a thickness that is included in a range of approximately 16.5 nm to approximately 20.5 nm or a thickness that is included in a range of approximately 16 nm to approximately 21 nm.

Additionally, or alternatively, and as part of the tiered structure 420-1, at least one of semiconductor layers 510-1 or 510-2 may have a thickness that is included in a range of approximately 9 nm to approximately 11 nm. However, other values and ranges for a thickness of the semiconductor layers 510-1 or 510-2 are within the scope of the present disclosure, such as a thickness that is included in a range of approximately 8.5 nm to approximately 11.5 nm or a thickness that is included in a range of approximately 8 nm to approximately 12 nm.

Additionally, or alternatively, and as part of the tiered structure 420-1, at least one of the oxide layers 515-1, 515-2, 515-3, or 515-4 may have a thickness that is included in a range of approximately 1 nm to approximately 2 nm. However, other values and ranges for the thicknesses of the oxide layers 515-1, 515-2, 515-3, or 515-4 are within the scope of the present disclosure, such as a thickness that is included in a rage of approximately 0.5 nm to approximately 2.5 nm.

In some embodiments, layers of the tiered structure 420-1 may be formed in a memory block region (e.g., the memory block region 405), a periphery region (e.g., the periphery region 485), or a staircase region (e.g., the staircase region 410) of a semiconductor die. In some embodiments, portions of a layer within the memory block region, the periphery region, or the staircase region may be formed simultaneously (e.g., portions of the oxide layer 515-1 in the memory block region 405, the periphery region 485, or the staircase region 410 may be deposited simultaneously using a single deposition operation). Alternatively, and in some embodiments, portions of a layer within the memory block region, the periphery region, or the staircase region may be formed separately (e.g., portions of the oxide layer 515-1 in the memory block region 405, the periphery region 485, or the staircase region 410 may be deposited separately using two or more deposition operations).

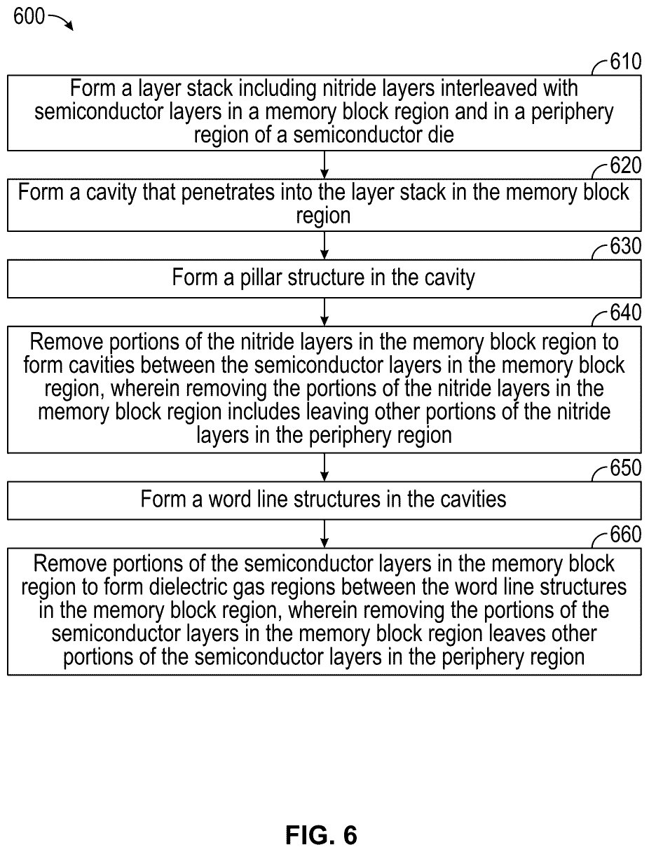

As described in greater detail in connection with FIGS. 6 and 8A-8G, a replacement operation may be performed that replaces portions of the nitride layers 505-1, 505-2, and 505-3 in the memory block region or the staircase region with word line structures (e.g., the access lines 425). However, such a replacement operation may leave the tiered structure 420-1 in the periphery region.

As further shown in FIG. 5, a bottom-most layer of the tiered structure 420-2 includes the semiconductor layer. As a result, and in some embodiments, the tiered-structure 440-2 is referred to as an “SNSNS” configuration.

As part of the tiered structure 420-2, at least one of the semiconductor layers 510-3, 510-4, or 510-5 may have a thickness that is included in a range of approximately 17 nm to approximately 20 nm. However, other values and ranges for the thickness of the semiconductor layers 510-3, 510-4, or 510-5 are within the scope of the present disclosure, such as a thickness that is included in a range of approximately 16.5 nm to approximately 20.5 nm or a thickness that is included in a range of approximately 16 nm to approximately 21 nm.

Additionally, or alternatively, and as part of the tiered structure 420-2, at least one of the nitride layers 505-4 or 505-5 may have a thickness that is included in a range of approximately 9 nm to approximately 11 nm. However, other values and ranges for a thickness of the nitride layers 505-4 and 505-4 are within the scope of the present disclosure, such as a thickness that is included in a range of approximately 8.5 nm to approximately 11.5 nm or a thickness that is included in a range of approximately 8 nm to approximately 12 nm.

Additionally, or alternatively, and as part of the tiered structure 420-2 at least one of the oxide layers 515-5, 515-6, 515-7, or 515-8 may have a thickness that is included in a range of approximately 1 nm to approximately 2 nm. However, other values and ranges for a thickness of the oxide layers 515-5, 515-6, 515-7, or 515-8 are within the scope of the present disclosure, such as a thickness that is included in a rage of approximately 0.5 nm to approximately 1.5 nm.

In some embodiments, layers of the tiered structure 420-2 may be formed in a memory block region (e.g., the memory block region 405), a periphery region (e.g., the periphery region 485), or a staircase region (e.g., the staircase region 410) of a semiconductor die. In some embodiments, portions of a layer within the memory block region, the periphery region, or the staircase region may be formed simultaneously (e.g., portions of the oxide layer 515-5 in the memory block region 405, the periphery region 485, or the staircase region 410 may be deposited simultaneously using a single deposition operation). Alternatively, and in some embodiments, portions of a layer within the memory block region, the periphery region, or the staircase region may be formed separately (e.g., portions of the oxide layer 515-5 in the memory block region 405, the periphery region 485, or the staircase region 410 may be deposited separately using two or more deposition operations).

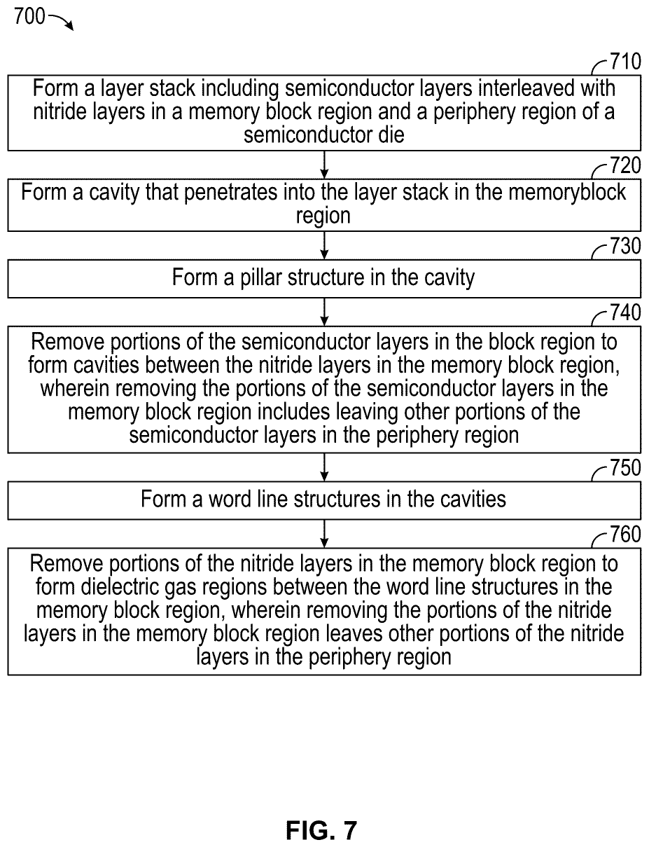

As described in greater detail in connection with FIGS. 7 and 9A-9G, a replacement operation may be performed that replaces portions of the semiconductor layers 510 in the memory block region or the staircase region with word line structures (e.g., the access lines 425). However, such a replacement operation may leave the tiered structure 420-2 in the periphery region.

As described in connection with FIGS. 4 and 5, a tiered structure 420 (e.g., the tiered structure 420-1 or the tiered structure 420-2) includes a combination of nitride layers 505, semiconductor layers 510, and oxide layers 515. In some embodiments, and in a case where the semiconductor layers 510 include crystalline silicon, germanium may be substituted for the nitride layers. Accordingly, a configuration of the tiered structure 420 may be a “SGeSGeS” configuration or a “GeSGeSGe” configuration. In such a case, substituting germanium for nitride may eliminate the need for the oxide layers 515 in the tiered structure 420.

As indicated above, FIG. 5 is provided as an example. Other examples may differ from what is described with regard to FIG. 5.

As described in connection with FIG. 4A, FIG. 4B, and FIG. 5, and in some embodiments, a semiconductor device (e.g., the memory device structure 400) includes an array region (e.g., the memory block region 405). The array region includes a pillar structure (e.g., the pillar structure 435), a first word line structure (e.g., the access line 425-1) connected to the pillar structure along a first level (e.g., the level 470-1) that is approximately orthogonal to the pillar structure, a second word line structure (e.g., the access line 425-2) connected to the pillar structure along a second level (e.g., the level 470-2) that is approximately parallel to the first level, and a dielectric gas region (e.g., the dielectric gas region 475-1) along a third level (e.g., the level 470-4) that is between the first level and the second level. The semiconductor device further includes a periphery region (e.g., the periphery region 485) proximate the array region that includes a tiered structure (e.g., the tiered structure 420). The tiered structure includes a first layer formed along the first level, a second layer formed along the second level, and a third layer formed along the third level between the first layer and the second layer, wherein the third layer includes a portion of either one of a semiconductor layer (e.g., the semiconductor layer 510) or a nitride layer (e.g., the nitride layer 505).

Alternatively, and in some embodiments, a semiconductor device (e.g., the memory device structure 400) includes an array region (e.g., the memory block region 405). The array region includes a pillar structure (e.g., the pillar structure 435), a first word line structure (e.g., the access line 425-1) connected to the pillar structure along a first level (e.g., the level 470-1) that is approximately orthogonal to the pillar structure, a second word line structure (e.g., the access line 425-2) connected to the pillar structure along a second level (e.g., the level 470-2) that is approximately parallel to the first level, and a dielectric gas region (e.g., the dielectric gas region 475-1) along a third level (e.g., the level 470-4) that is between the first level and the second level. The semiconductor device further includes periphery region (e.g., the periphery region 485) proximate the array region that includes a tiered structure (e.g., the tiered structure 420). The tiered structure includes a first layer formed along the first level, a second layer formed along the second level, and a third layer formed along the third level between the first layer and the second layer, wherein the third layer includes a portion of either one of a crystalline silicon layer (e.g., the semiconductor layer 510) or a germanium layer.

Alternatively, and in some embodiments, a semiconductor device (e.g., the memory device structure 400) includes a memory block region (e.g., the memory block region 405). The memory block region includes a pillar structure (e.g., the pillar structure 435), a first word line structure (e.g., the access line 425-1) that extends away from the pillar structure along a first level (e.g., the level 470-1) that is approximately orthogonal to the pillar structure, a second word line structure (e.g., the access line 425-2) that extends away from the pillar structure along a second level (e.g., the level 470-2) that is separated from the first level and that is approximately parallel to the first level, and a dielectric gas region (e.g., the dielectric gas region 475-1) along a third level (e.g., the level 470-4) that is between facing surfaces of the first word line structure and the second word line structure and that is approximately parallel to the first level and the second level. The semiconductor device further includes a periphery region (e.g., the periphery region 485) proximate the memory block region that includes a tiered structure (e.g., the tiered structure 420-1). The tiered structure includes a first nitride layer (e.g., the nitride layer 505-1) formed along the first level; a second nitride layer (e.g., the nitride layer 505-2) formed along the second level, and a semiconductor layer (e.g., the semiconductor layer 510-1) formed along the third level and between the first nitride layer and the second nitride layer.

Alternatively, and in some embodiments, a semiconductor device (e.g., the memory device structure 400) includes a memory block region (e.g., the memory block region 405). The memory block region includes a pillar structure (e.g., the pillar structure 435), a first word line structure (e.g., the access line 425-1) that extends away from the pillar structure along a first level (e.g., the level 425-1) that is approximately orthogonal to the pillar structure, a second word line structure (e.g., the access line 425-2) that extends away from the pillar structure along a second level (e.g., the level 470-2) that is separated from the first level and that is approximately parallel to the first level, and a dielectric gas region (e.g., the dielectric gas region 475-1) along a third level (e.g., the level 470-4) that is between facing surfaces of the first word line structure and the second word line structure and that is approximately parallel to the first level and the second level. The semiconductor device further includes a periphery region (e.g., the periphery region 485) proximate the memory block region that includes a tiered structure (e.g., the tiered structure 420-1). The tiered structure includes a first germanium layer formed along the first level, a second germanium layer formed along the second level, and a semiconductor layer (e.g., the semiconductor layer 510-1) formed along the third level and between the first nitride layer and the second nitride layer.

Alternatively and in some embodiments, a semiconductor device (e.g., the memory device structure 400) includes a memory block region (e.g., the memory block region 405). The memory block region includes a pillar structure (e.g., the pillar structure 435), a first word line structure (e.g., the access line 425-1) that extends away from the pillar structure along a first level (e.g., the level 470-1) that is approximately orthogonal to the pillar structure, a second word line structure (e.g., the access line 425-2) that extends away from the pillar structure along a second level (e.g., the level 470-2) that is separated from the first level and that is approximately parallel to the first level, and a dielectric gas region (e.g., the dielectric gas region 475-1) along a third level (e.g., the level 470-4) that is between facing surfaces of the first word line structure and the second word line structure and that is approximately parallel to the first level and the second level. The semiconductor device further includes a periphery region (e.g., the periphery region 485) proximate the memory block region that includes a tiered structure (e.g., the tiered structure 420-2). The tiered structure includes a first semiconductor layer (e.g., the semiconductor layer 510-3) formed along the first level, a second semiconductor layer (e.g., the semiconductor layer 510-4) formed along the second level, and a nitride layer (e.g., the nitride layer 505-4) formed along the third level and between the first nitride layer and the second nitride layer.

As described in greater detail in connection with FIGS. 4, 5, 8A-8G, and 9A-9G, use of a layer stack that includes the nitride layers interleaved with the semiconductor layers may enable formation of the word line structure with negligible damage to the pillar structure, negligible oxidation to the word line structures, or a reduced likelihood of electrical shorting between the word line structures. In this way, a quality, a reliability, or a performance of the semiconductor device (e.g., a NAND memory device) is improved relative to another semiconductor device formed using another layer stack including nitride layers interleaved with oxide layers. By improving the quality, reliability, or the performance of the semiconductor device, an amount of resources used to support a market consuming the semiconductor device (e.g., labor, semiconductor manufacturing tools, raw materials, or computing resources) is reduced.

FIG. 6 is a flowchart of an example method 600 of forming an integrated assembly or memory device having dielectric gas regions between word line structures using a layer stack including interleaved semiconductor and nitride layers. In some embodiments, and as described in greater detail in connection with FIGS. 8A-8G, one or more process blocks of FIG. 6 may be performed by various semiconductor manufacturing equipment.

As shown in FIG. 6, the method 600 may include forming a layer stack including nitride layers (e.g., the nitride layers 505) interleaved with semiconductor layers (e.g., the semiconductor layers 510) in a memory block region (e.g., the memory block region 405) and in a periphery region (e.g., the periphery region 485) of a semiconductor die (e.g., the memory device structure 400) (block 610). As further shown in FIG. 6, the method 600 may include forming a cavity that penetrates into the layer stack in the memory block region (block 620). As further shown in FIG. 6, the method 600 may include forming a pillar structure (e.g., the pillar structure 435) in the cavity (block 630). As further shown in FIG. 6, the method 600 may include removing portions of the nitride layers in the memory block region to form cavities between the semiconductor layers in the memory block region, wherein removing the portions of the nitride layers in the memory block region includes leaving other portions of the nitride layers in the periphery region (block 640). As further shown in FIG. 6, the method 600 may include forming word line structures (e.g., the access lines 425) in the cavities (block 650). As further shown in FIG. 6, the method 600 may include removing portions of the semiconductor layers in the memory block region to form dielectric gas regions (e.g., the dielectric gas regions 475) between the word line structures in the memory block region, wherein removing the portions of the semiconductor layers in the memory block region leaves other portions of the semiconductor layers in the periphery region (block 660).

The method 600 may include additional aspects, such as any single aspect or any combination of aspects described below or in connection with one or more other methods described elsewhere herein.

In a first aspect, forming the layer stack including the nitride layers interleaved with the semiconductor layers includes oxidizing ends of the semiconductor layers.

In a second aspect, alone or in combination with the first aspect, forming the layer stack including nitride layers interleaved with semiconductor layers includes forming oxide layers (e.g., the oxide layers 515) between the nitride layers and the semiconductor layers, wherein forming the oxide layers includes using a deposition operation that deposits portions of the oxide layers in the memory block region and portions of the oxide layers in the periphery region simultaneously.

In a third aspect, alone or in combination with one or more of the first and second aspects, forming the cavity includes etching a high aspect ratio cavity using a cryogenic etch operation.

In a fourth aspect, alone or in combination with one or more of the first through third aspects, removing the portions of the nitride layers includes exhuming the portions of the nitride layers using a hot phosphorous solution.

In a fifth aspect, alone or in combination with one or more of the first through fourth aspects, forming the layer stack includes forming at least one of the semiconductor layers using a material including a crystalline structure, forming at least one of the semiconductor layers using a material including a polycrystalline structure, or forming at least one of the semiconductor layers using a material including an amorphous structure.

In a sixth aspect, alone or in combination with one or more of the first through fifth aspects, the method 600 includes forming oxide caps on ends of the word line structures prior to removing the portions of the semiconductor layers.

Although FIG. 6 shows example blocks of the method 600, in some embodiments, the method 600 may include additional blocks, fewer blocks, different blocks, or differently arranged blocks than those depicted in FIG. 6. In some embodiments, the method 600 may include forming the access lines 425, an integrated assembly that includes the access lines 425, any part described herein of the access lines 425, or any part described herein of an integrated assembly that includes the access lines 425. For example, the method 600 may include forming one or more of the tiered structure 420-1, the pillar structure 435, the access lines 425, and or the dielectric gas regions 475. Furthermore, and in a case in which the semiconductor layers 510 include crystalline silicon, a variation of the method 600 may include using germanium layers in place of the nitride layers 505.

FIG. 7 is a flowchart of an example method 700 of forming an integrated assembly or memory device having dielectric gas regions between word line structures using a layer stack including interleaved semiconductor and nitride layers. In some embodiments, one or more process blocks of FIG. 7 may be performed by various semiconductor manufacturing equipment.

As shown in FIG. 7, the method 700 may include forming a layer stack including semiconductor layers (e.g., the semiconductor layers 510) interleaved with nitride layers (e.g., the nitride layers 505) in a memory block region (e.g., the memory block region 405) and a periphery region (e.g., the periphery region 485) of a semiconductor die (e.g., the memory device structure 400) (block 710). As further shown in FIG. 7, the method 700 may include forming a cavity that penetrates into the layer stack in the memory block region (block 720). As further shown in FIG. 7, the method 700 may include forming a pillar structure (e.g., the pillar structure 435) in the cavity (block 730). As further shown in FIG. 7, the method 700 may include removing portions of the semiconductor layers in the memory block region to form cavities between the nitride layers in the memory block region, wherein removing the portions of the semiconductor layers in the memory block region includes leaving other portions of the semiconductor layers in the periphery region (block 740). As further shown in FIG. 7, the method 700 may include forming word line structures (e.g., the access line 425) in the cavities (block 750). As further shown in FIG. 7, the method 700 may include removing portions of the nitride layers in the memory block region to form dielectric gas regions (e.g., the dielectric gas regions 475) between the word line structures in the memory block region, wherein removing the portions of the nitride layers in the memory block region leaves other portions of the nitride layers in the periphery region (block 760).

The method 700 may include additional aspects, such as any single aspect or any combination of aspects described below or in connection with one or more other methods described elsewhere herein.

In a first aspect, forming the layer stack includes forming oxide layers (e.g., the oxide layers 515) between the nitride layers and the semiconductor layers, wherein forming the oxide layers includes using deposition operations that deposit portions of the oxide layers in the memory block region and portions of the oxide layers in the periphery region separately.

In a second aspect, alone or in combination with the first aspect, forming the cavity includes etching a high aspect ratio cavity using a dry etch operation.

In a third aspect, alone or in combination with one or more of the first and second aspects, forming the layer stack includes forming at least one of the semiconductor layers using silicon, forming at least one of the semiconductor layers using silicon germanium, or forming at least one of the semiconductor layers using a silicon germanium compound.

In a fourth aspect, alone or in combination with one or more of the first through third aspects, removing the portions of the semiconductor layers includes exhuming at least one of the portions using a tetramethylammonium hydroxide solution.

In a fifth aspect, alone or in combination with one or more of the first through fourth aspects, the method 700 includes forming oxide caps on ends of the word line structures prior to removing the portions of the nitride layers.

Although FIG. 7 shows example blocks of the method 700, in some embodiments, the method 700 may include additional blocks, fewer blocks, different blocks, or differently arranged blocks than those depicted in FIG. 7. In some embodiments, the method 700 may include forming the access lines 425, an integrated assembly that includes the access lines 425, any part described herein of the access lines 425, or any part described herein of an integrated assembly that includes the access lines 425. For example, the method 700 may include forming one or more of the tiered structure 420-2, the pillar structure 435, the access lines 425, and or the dielectric gas regions 475. Furthermore, and in a case in which the semiconductor layers 510 include crystalline silicon, a variation of the method 700 may include using germanium layers in place of the nitride layers 505.

FIGS. 8A-8G are diagrammatic views showing formation of the memory device structure 400 at example process stages of an example process 800 of forming the memory device structure 400. In some embodiments, the process 800 described below in connection with FIGS. 8A-8G may correspond to the method 600 or one or more blocks of the method 600. However, the process described below is an example, and other example processes may be used to form the access lines 425, an integrated assembly that includes the access line 425, or one or more parts of the access lines 425 or an integrated assembly including the access lines 425. As shown in FIGS. 8A-8G, the process 800 is performed in the memory block region 405 of the memory device structure 400. Additionally, or alternatively, one or more portions of the process 800 may be performed in the periphery region 485 or the staircase region 410 of the memory device structure 400.

As shown in FIG. 8A, the process 800 includes forming a layer stack including the nitride layers 505-1, 505-2, and 505-3 that are interleaved with the semiconductor layers 510-1 and 510-2. In some embodiments, the process 800 includes forming the oxide layer 515-1 over or on the nitride layer 505-1, forming the oxide layer 515-2 over and or on the semiconductor layer 510-1, forming the oxide layer 515-3 over or on the nitride layer 505-2, and forming the oxide layer 515-4 over or on the semiconductor layer 510-2. In some embodiments, techniques to form one or more layers of the layer stack may include a semiconductor manufacturing tool (e.g., a deposition tool) performing a deposition operation.

In some embodiments, and as shown in FIG. 8A, the process 800 may include forming an oxidized end 805-1 of the semiconductor layer 510-1 and the oxidized end 805-2 of the semiconductor layer 510-2. In other words, the process 800 may include oxidizing ends of the semiconductor layers 510-1 and 510-2. In some embodiments, techniques to oxidize the ends of the semiconductor layers 510-1 and 510-2 may include a semiconductor manufacturing tool (e.g., a furnace tool) performing an oxidizing operation. As described in greater detail in connection with FIGS. 8D and 8E, the oxidized ends 805-1 and 805-2 may preserve the semiconductor layers 510-1 and 510-2 during a nitride replacement operation or during a word line structure recessing operation.

As shown in FIG. 8B, the process 800 includes forming a cavity 810 that penetrates into or through the layer stack. In some embodiments, techniques to form the cavity 810 include a semiconductor manufacturing tool (e.g., an etch tool) forming a high aspect ratio (HAR) cavity (e.g., a cavity with a substantially greater depth than width) using a cryogenic etch operation, during which a gas (e.g., a fluorine-based plasma) etches the cavity 810 at a temperature which may be less than approximately 100 degrees Celsius (° C.). Alternatively, and in some embodiments, techniques to form the cavity 810 may include a semiconductor manufacturing tool (e.g., an etch tool) using a dry etch operation.

As shown in FIG. 8C, the process 800 includes forming the pillar structure 435 in the cavity 810. In some embodiments, techniques to form the pillar structure 435 include a semiconductor manufacturing tool (e.g., a deposition tool) performing a series or a sequence of deposition operations to form the pillar structure 435 from multiple dielectric or conductive layers. In other words, forming the pillar structure 435 may include forming a multi-layer pillar structure.

As shown in FIG. 8D, and as part of a replacement operation, the process 800 includes removing the nitride layers 505-1, 505-2, and 505-3 to form cavities 815-1, 815-2, and 815-3. As shown in FIG. 8D, the cavity 815-2 is between the semiconductor layers 510-1 and 510-2.

In some embodiments, techniques to remove the nitride layers 505-1, 505-2, and 505-3 include a semiconductor manufacturing tool (e.g., an etch tool) using a phosphorous-based etchant at an elevated temperature (e.g., a hot phosphorous etchant) to exhume the nitride layers 505-1, 505-2, and 505-3 through cavities or pathways adjacent to the nitride layers 505-1, 505-2, and 505-3. As shown in FIG. 8D, the oxidized regions 805-1 and 805-2 may preserve the semiconductor layers 510-1 and 510-2 during removal of the nitride layers 505-1, 505-2, and 505-3.

As shown in FIG. 8E, the process 800 includes forming the access lines 425-1, 425-2, and 425-3 in the cavities 815-1, 815-2, and 815-3. In some embodiments, techniques to form the access lines 425-1, 425-2, and 425-3 include a semiconductor manufacturing tool (e.g., a deposition tool) performing a series or a sequence of deposition operations to form an outer high-k dielectric layer and an inner conductive layer. In other words, forming the access lines 425-1, 425-2, and 425-3 may include forming multi-layer word line structures.

As further shown in FIG. 8E, the process 800 includes forming recesses 820-1, 820-2, and 820-3 in the access line 425-1, 425-2, and 425-3. In some embodiments, techniques to form the recesses 820-1, 820-2, and 820-3 include a semiconductor manufacturing tool (e.g., an etch tool) performing an etch operation to form the recesses 820-1, 820-2, and 820-3 in the access line 425-1, 425-2, and 425-3. As shown in FIG. 8E, the oxidized regions 805-1 and 805-2 may preserve the semiconductor layers 510-1 and 510-2 during formation of the recesses 820-1, 820-2, and 820-3.

As shown in FIG. 8F, and in some embodiments, the process 800 includes forming oxide end caps 825-1, 825-2, and 825-3 on ends of the access line 425-1, 425-2, and 425-3. In some embodiments, techniques to form the oxide end caps 825-1, 825-2, and 825-3 include a semiconductor manufacturing tool (e.g., a furnace tool) performing an oxidizing operation.

As shown in FIG. 8G, the process 800 includes removing the semiconductor layers 510-1 and 510-2 to form the dielectric gas regions 475-1 and 475-2. In some embodiments, techniques to remove the semiconductor layers 510-1 and 510-2 include a semiconductor manufacturing tool (e.g., an etch tool) using an etchant to remove the semiconductor layers 510-1 and 510-2. As an example, and in an implementation in which the semiconductor layers 510-1 and 510-2 include polysilicon, the semiconductor manufacturing tool may use a tetramethylammonium hydroxide etchant to exhume the semiconductor layers 510-1 and 510-2 through cavities or pathways adjacent to the semiconductor layers 510-1 and 510-2.

As shown in FIG. 8G, the dielectric gas region 475-1 is formed between facing surfaces of the access line 425-1 and 425-2. In some embodiments, the facing surfaces are surfaces of dielectric layers (e.g., outer high-k dielectric layers) of the access line 425-1 and 425-2. Additionally, or alternatively and as shown in FIG. 8G, the dielectric gas region 475-2 is formed between facing surfaces of the access line 425-2 and 425-3.

In some embodiments, one or more aspects of the process 800 are applicable to each of the regions of the memory device structure 400. For example, deposition operations described in connection with FIG. 8A may form the layer stack within the memory block region 405, the periphery region 485, or the staircase region 410 of the memory device structure 400. Additionally, or alternatively, one or more aspects of the process 800 may be applicable to only a subset of the regions of the semiconductor device. For example, after formation, a portion of the layer stack within the periphery region 485 may be masked from one or more operations used to remove the nitride layers 505-1, 505-2, and 505-3 or one or more operations used to remove the semiconductor layers 510-1 and 510-2. In other words, after the process 800 is performed, a portion of the layer stack (e.g., the tiered structure 420-1) may remain in the periphery region 485.

As indicated above, the process 800 described in connection with FIGS. 8A-8G is provided as an example. Other examples may differ from what is described with respect to FIGS. 8A-8G. For example, and for a case in which the semiconductor layers 510-1 and 510-2 include crystalline silicon, a variation of the process 800 may include substituting germanium layers for the nitride layers 505-1, 505-2, and 505-3. Furthermore, the structure shown in FIG. 8G may include the access lines 425 described elsewhere herein.

In process steps of FIGS. 8A-8G that describe forming material, such material may be formed, for example, using chemical vapor deposition, atomic layer deposition, physical vapor deposition, or another deposition operation. In process steps of FIGS. 8A-8G that describe removing material, such material may be removed, for example, using a wet etching operation (e.g., wet chemical etching), a dry etching operation (e.g., plasma etching), an ion etching operation (e.g., sputtering or reactive ion etching), atomic layer etching, or another etching operation.

FIGS. 9A-9G are diagrammatic views showing formation of the memory device structure 400 at example process stages of an example process 900 of forming the memory device structure 400. In some embodiments, the process 900 described below in connection with FIGS. 9A-9G may correspond to the method 700 or one or more blocks of the method 700. However, the process described below is an example, and other example processes may be used to form the access lines 425, an integrated assembly that includes the access lines 425, or one or more parts of the access lines 425 or an integrated assembly including the access lines 425. As shown in FIGS. 9A-9G, the process 900 is performed in the memory block region 405 of the memory device structure 400. Additionally, or alternatively, one or more portions of the process 900 may be performed in the periphery region 485 or the staircase region 410 of the memory device structure 400.

As shown in FIG. 9A, the process 900 includes forming a layer stack including the semiconductor layers 510-3, 510-4, and 510-5 that are interleaved with the nitride layers 505-4 and 505-5. In some embodiments, the process 900 includes forming the oxide layer 515-5 over or on the semiconductor layer 510-3, forming the oxide layer 515-6 over and or on the nitride layer 505-4, forming the oxide layer 515-7 over or on the semiconductor layer 510-4, and forming the oxide layer 515-8 over or on the nitride layer 505-5. In some embodiments, techniques to form one or more layers of the layer stack may include a semiconductor manufacturing tool (e.g., a deposition tool) performing a deposition operation.

As shown in FIG. 9B, the process 900 includes forming a cavity 905 that penetrates into or through the layer stack. In some embodiments, techniques to form the cavity 905 include a semiconductor manufacturing tool (e.g., an etch tool) forming an HAR cavity (e.g., a cavity with a substantially greater depth than width) using a cryogenic etch operation, during which a gas (e.g., a fluorine-based plasma) etches the cavity 905 at a temperature which may be less than approximately 100 degrees Celsius (° C.). Alternatively, and in some embodiments, techniques to form the cavity 905 may include a semiconductor manufacturing tool (e.g., an etch tool) using a dry etch operation.

As shown in FIG. 9C, the process 900 includes forming the pillar structure 435 in the cavity 905. In some embodiments, techniques to form the pillar structure 435 include a semiconductor manufacturing tool (e.g., a deposition tool) performing a series or a sequence of deposition operations to form the pillar structure 435 from multiple dielectric or conductive layers.

As shown in FIG. 9D, and as part of a replacement operation, the process 900 includes removing the semiconductor layers 510-3, 510-4, and 510-5 to form cavities 910-1, 910-2, and 910-3. As shown in FIG. 9D, the cavity 910-2 is between the semiconductor layers nitride layers 505-4 and 505-5.

In some embodiments, techniques to remove the semiconductor layers 510-3, 510-4, and 510-5 include a semiconductor manufacturing tool (e.g., an etch tool) using an etchant to remove the semiconductor layers 510-3, 510-4, and 510-5. As an example, and in an implementation in which the semiconductor layers 510-3, 510-4, and 510-5 include polysilicon, the semiconductor manufacturing tool may use a tetramethylammonium hydroxide etchant to exhume the semiconductor layers 510-3, 510-4, and 510-5 through cavities or pathways adjacent the semiconductor layers 510-3, 510-4, and 510-5.

As shown in FIG. 9E, the process 900 includes forming the access line 425-1, 425-2, and 425-3 in the cavities 910-1, 910-2, and 910-3. In some embodiments, techniques to form the access lines 425-1, 425-2, and 425-3 include a semiconductor manufacturing tool (e.g., a deposition tool) performing a series or a sequence of deposition operations to form an outer high-k dielectric layer and an inner conductive layer.

As further shown in 9E, the process 900 includes forming recesses 915-1, 915-2, and 915-3 in the access lines 425-1, 425-2, and 425-3. In some embodiments, techniques to form the recesses 915-1, 915-2, and 915-3 include a semiconductor manufacturing tool (e.g., an etch tool) performing an etch operation to form the recesses 915-1, 915-2, and 915-3 in the access lines 425-1, 425-2, and 425-3.

As shown in FIG. 9F, and in some embodiments, the process 900 includes forming the oxide end caps 820-1, 820-2, and 820-3 on ends of the access lines 425-1, 425-2, and 425-3. In some embodiments, techniques to form the oxide end caps 820-1, 820-2, and 820-3 include a semiconductor manufacturing tool (e.g., a furnace tool) performing an oxidizing operation.

As shown in FIG. 9G, the process 900 includes removing the nitride layers 505-4 and 505-5 to form the dielectric gas regions 475-1 and 475-2. In some embodiments, techniques to remove the nitride layers 505-4 and 505-5 include a semiconductor manufacturing tool (e.g., an etch tool) using a phosphorous-based etchant at an elevated temperature (e.g., a hot phosphorous etchant) to exhume the nitride layers 505-4 and 505-5 through cavities or pathways adjacent to the nitride layers 505-4 and 505-5.

As shown in FIG. 9G, the dielectric gas region 475-1 is formed between facing surfaces of the access line 425-1 and 425-2. In some embodiments, the facing surfaces are surfaces of dielectric layers (e.g., outer high-k dielectric layers) of the access lines 425-1 and 425-2. Additionally, or alternatively and as shown in FIG. 9G, the dielectric gas region 475-2 is formed between facing surfaces of the access line 425-2 and 425-3. In some embodiments, the facing surfaces are surfaces of dielectric layers (e.g., outer high-k dielectric layers) of the access line 425-2 and 425-3.

In some embodiments, one or more aspects of the process 900 are applicable to each of the regions of the memory device structure 400. For example, deposition operations described in connection with FIG. 9A may form the layer stack within the memory block region 405, the periphery region 485, or the staircase region 410 of the memory device structure 400. Additionally, or alternatively, one or more aspects of the process 900 may be applicable to only a subset of the regions of the semiconductor device. For example, after formation, a portion of the layer stack within the periphery region 485 may be masked from one or more operations used to remove the semiconductor layers 510-3, 510-4, and 510-5 or masked from one or more operations used to remove the nitride layers 505-4 and 505-5. In other words, after the process 900 is performed, a portion of the layer stack (e.g., the tiered structure 420-2) may remain in the periphery region 485.

As indicated above, the process 900 described in connection with FIGS. 9A-9G is provided as an example. Other examples may differ from what is described with respect to FIGS. 9A-9G. For example, and for a case in which the semiconductor layers 510-3, 510-4, and 510-5 include crystalline silicon, a variation of the process 900 may include substituting germanium layers for the nitride layers 505-4 and 505-5. Furthermore, the structure shown in FIG. 9G may include the access lines 425 described elsewhere herein.

In process steps of FIGS. 9A-9G that describe forming material, such material may be formed use chemical vapor deposition, atomic layer deposition, physical vapor deposition, or another deposition operation. In process steps of FIGS. 9A-9G that describe removing material, such material may be removed, for example, using a wet etching operation (e.g., wet chemical etching), a dry etching operation (e.g., plasma etching), an ion etching operation (e.g., sputtering or reactive ion etching), atomic layer etching, or another etching operation.

In some embodiments, a semiconductor device includes an array region, comprising: a pillar structure; a first word line structure connected to the pillar structure along a first level that is approximately orthogonal to the pillar structure; a second word line structure connected to the pillar structure along a second level, wherein the second level is approximately parallel to the first level; and a dielectric gas region along a third level that is between the first level and the second level; and a periphery region proximate the array region, comprising: a tiered structure, comprising: a first layer formed along the first level; a second layer formed along the second level; and a third layer formed along the third level and between the first layer and the second layer, wherein the third layer includes a portion of either one of a semiconductor layer or a nitride layer.

In some embodiments, a method includes forming a layer stack including nitride layers interleaved with semiconductor layers in a memory block region and in a periphery region of a semiconductor die, forming a cavity that penetrates into the layer stack in the memory block region; forming a pillar structure in the cavity; removing portions of the nitride layers in the memory block region to form cavities between the semiconductor layers in the memory block region, wherein removing the portions of the nitride layers in the memory block region includes leaving other portions of the nitride layers in the periphery region; forming word line structures in the cavities; and removing portions of the semiconductor layers in the memory block region to form dielectric gas regions between the word line structures in the memory block region, wherein removing the portions of the semiconductor layers in the memory block region leaves other portions of the semiconductor layers in the periphery region.

In some embodiments, a method includes forming a layer stack including semiconductor layers interleaved with nitride layers in a memory block region and a periphery region of a semiconductor die; forming a cavity that penetrates into the layer stack in the memory block region; forming a pillar structure in the cavity; removing portions of the semiconductor layers in the memory block region to form cavities between the nitride layers in the memory block region, wherein removing the portions of the semiconductor layers in the memory block region includes leaving other portions of the semiconductor layers in the periphery region; forming word line structures in the cavities; and removing portions of the nitride layers in the memory block region to form dielectric gas regions between the word line structures in the memory block region, wherein removing the portions of the nitride layers in the memory block region leaves other portions of the nitride layers in the periphery region.

The foregoing disclosure provides illustration and description but is not intended to be exhaustive or to limit the embodiments to the precise forms disclosed. Modifications and variations may be made in light of the above disclosure or may be acquired from practice of the embodiments described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, or assembly in use or operation in addition to the orientations depicted in the figures. A structure or assembly may be otherwise oriented (rotated 90 degrees or at other orientations), and the spatially relative descriptors used herein may be interpreted accordingly. Furthermore, the cross-sectional views in the figures only show features within the levels of the cross-sections, and do not show materials behind the levels of the cross-sections, unless indicated otherwise, in order to simplify the drawings.

As used herein, the terms “substantially” and “approximately” mean “within reasonable tolerances of manufacturing and measurement.” As used herein, the term “formed” may, depending on the context, refer to a state or a position of a first feature relative to a second feature, and does not imply any specific method or sequence of formation.

As used herein, “interleaved” means an arranged sequence two or more items, where as part of the arranged sequence the two or more items may alternate with one another or have additional intervening items. As an example, “a interleaved with b” is intended to cover the arranged sequence of a-b-a-b-a, where a and b alternate with one another. Furthermore, “a interleaved with b” is intended to cover the arranged sequence of a-b-c-a-b-c-a, a-c-b-a-c-b-a, where c intervenes between groupings of a and b. Furthermore, “a interleaved with b” is intended to cover the arranged sequence of a-c-b-a-c-b-a, where c intervenes between a and b.

As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims or disclosed in the specification, these combinations are not intended to limit the disclosure of embodiments described herein. Many of these features may be combined in ways not specifically recited in the claims or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device, comprising:
an array region, comprising:
a pillar structure;
a first word line structure connected to the pillar structure along a first level that is approximately orthogonal to the pillar structure;
a second word line structure connected to the pillar structure along a second level,
wherein the second level is approximately parallel to the first level; and
a dielectric gas region along a third level that is between the first level and the second level; and
a periphery region proximate the array region, comprising:
a tiered structure, comprising:
a first layer formed along the first level;
a second layer formed along the second level; and
a third layer formed along the third level and between the first layer and the second layer,
wherein the third layer includes a portion of either one of a semiconductor layer or a nitride layer.

2. The semiconductor device of claim 1, wherein the first layer is a first nitride layer and the second layer is a second nitride layer when the third layer includes a portion of the semiconductor layer.

3. The semiconductor device of claim 1, wherein the dielectric gas region is formed by replacing an additional portion of the semiconductor layer, the portion and the additional portion of the semiconductor layer being different from each other.

4. The semiconductor device of claim 1, wherein the first layer is a first semiconductor layer and the second layer is a second semiconductor layer when the third layer includes a portion of the nitride layer.

5. The semiconductor device of claim 1, wherein a material of the semiconductor layer comprises:
silicon,
germanium, or
a silicon-germanium compound.

6. The semiconductor device of claim 1, wherein at least one of the first word line structure or the second word line structure comprises:
an inner conductive layer; and
an outer high-k dielectric layer.

7. The semiconductor device of claim 1, further comprising:
a first oxide layer between a first nitride layer and the semiconductor layer; and
a second oxide layer between a second nitride layer and the semiconductor layer.

8. The semiconductor device of claim 1, wherein a material of the semiconductor layer comprises:
a crystalline structure,
a polycrystalline structure, or
an amorphous structure.

9. The semiconductor device of claim 1, wherein at least one of the first word line structure or the second word line structure comprises:
an inner conductive layer, and
an outer high-k dielectric layer.

10. The semiconductor device of claim 1, further comprising:
a staircase region including portions of the first word line structure and the second word line structure,
wherein the dielectric gas region extends into the staircase region between the first word line structure and the second word line structure.

11. The semiconductor device of claim 10, wherein the dielectric gas region that extends into the staircase region between the first word line structure and the second word line structure extends to or beyond a central axis of a contact pillar that connects with the second word line structure.

12. A method, comprising:
forming a layer stack including nitride layers interleaved with semiconductor layers in a memory block region and in a periphery region of a semiconductor die,
forming a cavity that penetrates into the layer stack in the memory block region;
forming a pillar structure in the cavity;
removing portions of the nitride layers in the memory block region to form cavities between the semiconductor layers in the memory block region,
wherein removing the portions of the nitride layers in the memory block region includes leaving other portions of the nitride layers in the periphery region;
forming word line structures in the cavities; and
removing portions of the semiconductor layers in the memory block region to form dielectric gas regions between the word line structures in the memory block region,
wherein removing the portions of the semiconductor layers in the memory block region leaves other portions of the semiconductor layers in the periphery region.

13. The method of claim 12, wherein forming the layer stack including the nitride layers interleaved with the semiconductor layers includes:
oxidizing ends of the semiconductor layers.

14. The method of claim 12, wherein forming the layer stack including nitride layers interleaved with semiconductor layers includes:
forming oxide layers between the nitride layers and the semiconductor layers,
wherein forming the oxide layers includes using a deposition operation that deposits portions of the oxide layers in the memory block region and portions of the oxide layers in the periphery region simultaneously.

15. The method of claim 12, wherein forming the cavity includes:
etching a high aspect ratio cavity using a cryogenic etch operation.

16. The method of claim 12, wherein removing the portions of the nitride layers includes:
exhuming the portions of the nitride layers using a hot phosphorous etchant.

17. The method of claim 12, wherein forming the layer stack includes:
forming at least one of the semiconductor layers using a material including a crystalline structure,
forming at least one of the semiconductor layers using a material including a polycrystalline structure, or
forming at least one of the semiconductor layers using a material including an amorphous structure.

18. The method of claim 12, further comprising:
forming oxide caps on ends of the word line structures prior to removing the portions of the semiconductor layers.

19. A method, comprising:
forming a layer stack including semiconductor layers interleaved with nitride layers in a memory block region and a periphery region of a semiconductor die;
forming a cavity that penetrates into the layer stack in the memory block region;
forming a pillar structure in the cavity;
removing portions of the semiconductor layers in the memory block region to form cavities between the nitride layers in the memory block region,
wherein removing the portions of the semiconductor layers in the memory block region includes leaving other portions of the semiconductor layers in the periphery region;
forming word line structures in the cavities; and
removing portions of the nitride layers in the memory block region to form dielectric gas regions between the word line structures in the memory block region,
wherein removing the portions of the nitride layers in the memory block region leaves other portions of the nitride layers in the periphery region.

20. The method of claim 19, wherein forming the layer stack includes:
forming oxide layers between the nitride layers and the semiconductor layers,
wherein forming the oxide layers includes using deposition operations that deposit portions of the oxide layers in the memory block region and portions of the oxide layers in the periphery region separately.

21. The method of claim 19, wherein forming the cavity includes:
etching a high aspect ratio cavity using a dry etch operation.

22. The method of claim 19, wherein forming the layer stack includes:
forming at least one of the semiconductor layers using silicon,
forming at least one of the semiconductor layers using silicon germanium, or
forming at least one of the semiconductor layers using a silicon germanium compound.

23. The method of claim 19, wherein removing the portions of the semiconductor layers includes:
exhuming at least one of the portions using a tetramethylammonium hydroxide etchant.

24. The method of claim 19, further comprising:
forming oxide caps on ends of the word line structures prior to removing the portions of the nitride layers.
